(19) United States
(12) Patent Application Publication
(10) Pub. No.: US 2015/0333215 A1
(43) Pub. Date: Nov. 19, 2015

(54) NITRIDE SEMICONDUCTOR LIGHT-EMITTING DIODE

(71) Applicant: Panasonic Intellectual Property Management Co., Ltd., Osaka (JP)

(72) Inventors: AKIRA INOUE, Osaka (JP); RYOU KATO, Osaka (JP)

(21) Appl. No.: 14/505,751

(22) Filed: Oct. 3, 2014

(30) Foreign Application Priority Data
May 13, 2014 (JP) 2014-099183

(51) Int. Cl. H01L 33/06; H01L 33/32

(52) U.S. Cl. CPC H01L 33/06; H01L 33/32

(57) ABSTRACT

Provided is a nitride semiconductor light-emitting diode in which efficiency in a low current density is prevented from being decreased. The nitride semiconductor light-emitting diode comprises a second n-type nitride semiconductor layer. An active layer has a principal surface of an m-plane having an off angle of not less than 0 degrees and not more than 15 degrees. Either of the following requirement (A) and (B) is satisfied; (A) the second n-type nitride semiconductor layer has a donor impurity concentration of not less than 3.0×10¹⁷ cm⁻³ and less than 1.5×10¹⁸ cm⁻³, and the p-type nitride semiconductor has an acceptor impurity concentration of not less than 5.0×10¹⁷ cm⁻³ and less than 1.0×10¹⁸ cm⁻³, or (B) the second n-type nitride semiconductor layer has a donor impurity concentration of not less than 3.0×10¹⁷ cm⁻³ and not more than 2.5×10¹⁸ cm⁻³, and the p-type nitride semiconductor has an acceptor impurity concentration of not less than 1.0×10¹⁸ cm⁻³.

### BACKGROUND

1. Technical Field

The present invention relates to a nitride semiconductor light-emitting diode.

2. Description of the Related Art

Japanese Patent Application laid-open Publication No. 2002-111056A discloses a light-emitting element. As shown in FIG. 5, in the light-emitting element disclosed therein, an n-type AlGaN layer 12 is formed on a sapphire substrate 10 and an n-type light emission layer 14 is formed thereupon; and a buffer layer 16 is formed thereupon and further a p-type AlGaN layer is formed thereupon. The buffer layer has its electron density higher than the hole density of the p-type AlGaN layer 18 and wider band gap energy than the n-type light emission layer. Consequently, holes injected into the buffer layer 16 are more than electrons injected into the p-type AlGaN layer 18 and the thickness of the buffer layer 16 is specified, so that the holes are injected into the n-type light emission layer 14. Light emission is therefore caused in the n-type light emission layer 14 with high light emission efficiency, so that the light emission efficiency of the light emitting element can be increased.

Japanese Patent Application laid-open Publication No. Hei 10-200214A discloses a gallium nitride light-emitting element having p-type dopant material diffusion-blocking layer. As shown in FIG. 6, in the gallium nitride light-emitting element disclosed therein, a buffer layer 102, an n-type GaN optical guide layer 106, a multiple quantum well active layer 107, a dissociation blocking layer 108, an n-type GaN diffusion blocking layer 114, etc., are laminated on a sapphire substrate 101. A p-type GaN optical guide layer 109, a clad layer 110, a p-type contact layer 111, a p-type electrode 112 and an n-type electrode 113 are formed. A diffusion blocking layer 114 is formed between the dissociation blocking layer 108 adjacent to the active layer 107 and the optical guide layer 19, thereby blocking a p-type dopant from diffusing into the active layer 114. This prevents the reduction of the inter-band transition probability of the active layer 114 and deviation from designed emission spectrum.

### SUMMARY

The present invention provides a nitride semiconductor light-emitting diode comprising:

an n-side electrode;

a p-side electrode;

a first n-type nitride semiconductor layer;

a p-type nitride semiconductor layer;

a second n-type nitride semiconductor layer; and

an active layer interposed between the first n-type nitride semiconductor layer and the p-type nitride semiconductor layer, wherein

the n-side electrode is electrically connected to the first n-type nitride semiconductor layer;

the p-side electrode is electrically connected to the p-type nitride semiconductor layer;

the active layer is composed of a single quantum well layer;

the single quantum well layer is formed of n-type InGaN;

the active layer has a principal surface of an m-plane having an off angle of not less than 0 degrees and not more than 15 degrees;

the active layer has a thickness of not less than 6 nanometers;

the second n-type nitride semiconductor layer is interposed between the active layer and the p-type nitride semiconductor layer;

either of the following requirement (A) and (B) is satisfied:

(A) the second n-type nitride semiconductor layer has a donor impurity concentration of not less than 3.0×10¹⁷ cm⁻³ and less than 1.5×10¹⁸ cm⁻³, and the p-type nitride semiconductor layer has an acceptor impurity concentration of not less than 5.0×10¹⁷ cm⁻³ and less than 1.0×10¹⁸ cm⁻³, or

(B) the second n-type nitride semiconductor layer has a donor impurity concentration of not less than 3.0×10¹⁷ cm⁻³ and not more than 2.5×10¹⁸ cm⁻³, and the p-type nitride semiconductor layer has an acceptor impurity concentration of not less than 1.0×10¹⁸ cm⁻³;

the second n-type nitride semiconductor layer has a thickness of not less than 25 nanometers; and

the following mathematical formula (I) is satisfied:

(Efficiency Decrease Degree at low current density ΔEQE@0.3 A/cm²)≦0.6 (I),

where

(Efficiency Decrease Degree at low current density ΔEQE@0.3 A/cm²)=(EQEmax−EQE@0.3 A/cm²)/EQEmax;

EQEmax represents the maximum of an external quantum efficiency of the nitride semiconductor light-emitting diode; and

EQE@0.3 A/cm² represents an external quantum efficiency of the nitride semiconductor light-emitting diode when a current of 0.3 A/cm² flows through the nitride semiconductor light-emitting diode.

The present invention provides a nitride semiconductor light-emitting diode in which efficiency at a low current density is prevented from being decreased.

### BRIEF DESCRIPTION OF THE DRAWINGS

FIG. 1 shows a cross-sectional view of a nitride semiconductor light-emitting diode according to the first embodiment.

FIG. 2 shows a cross-sectional view for describing an angle θ.

FIG. 3A is a graph showing a relation between the current density and the external quantum efficiency.

FIG. 3B is another graph showing a relation between the current density and the external quantum efficiency.

FIG. 4 shows a cross-sectional view of an m-plane nitride semiconductor light-emitting diode used in the simulation according to the example 1.

FIG. 5 shows a cross-sectional view of the nitride semiconductor light-emitting diode disclosed in Japanese Patent Application laid-open Publication No. 2002-111056A.

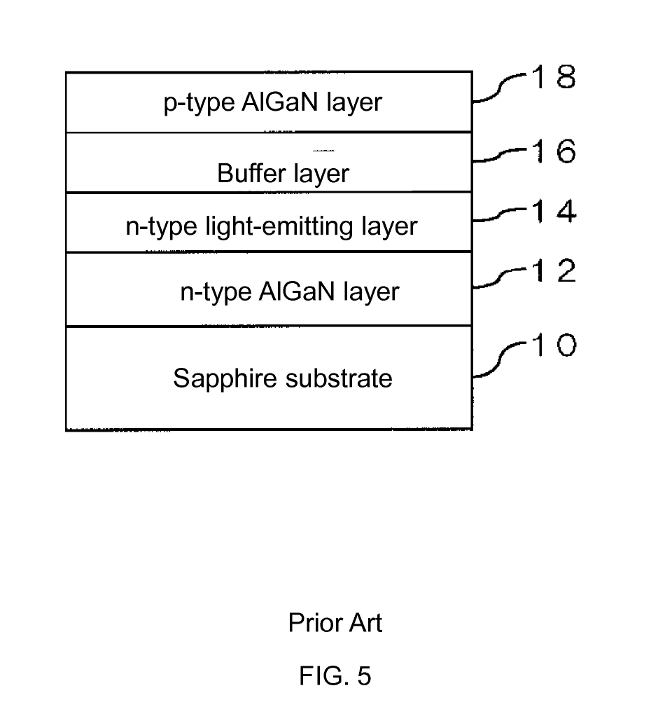

FIG. 6 shows a cross-sectional view of the nitride semiconductor light-emitting diode disclosed in Japanese Patent Application laid-open Publication No. Hei 10-200214A.

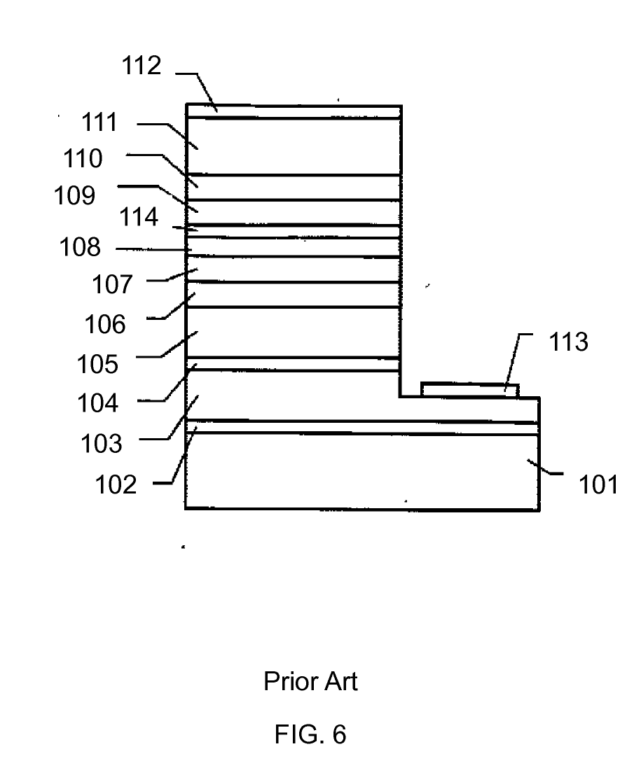

### DETAILED DESCRIPTION OF THE EMBODIMENTS

The embodiments of the present invention will be described below with reference to the drawings.

### First Embodiment

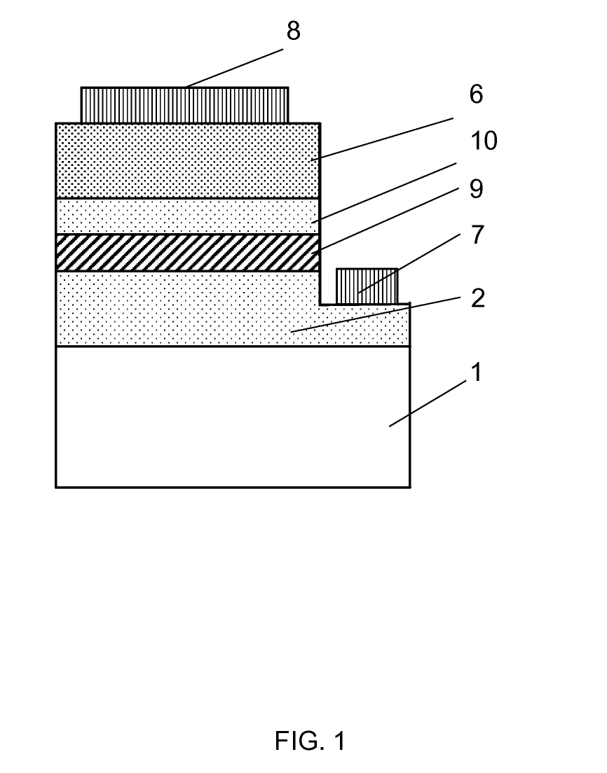

FIG. 1 shows a cross-sectional view of a nitride semiconductor light-emitting diode according to the first embodiment. Similarly to a typical nitride semiconductor light-emitting diode, the nitride semiconductor light-emitting diode according to the first embodiment comprises an n-side electrode 7, a first n-type nitride semiconductor layer 2, an active layer 9, a p-type nitride semiconductor layer 6, and a p-side electrode 8. The nitride semiconductor light-emitting diode according to the first embodiment further comprises a second n-type nitride semiconductor layer 10, which will be described later in more detail.

Similarly to a typical nitride semiconductor light-emitting diode, it is desirable that the nitride semiconductor light-emitting diode according to the first embodiment comprises a substrate 1. The first n-type nitride semiconductor layer 2, the active layer 9, the second n-type nitride semiconductor layer 10, and the p-type nitride semiconductor layer 6 are epitaxially grown on the substrate 1.

The n-side electrode 7 is electrically connected to the first n-type nitride semiconductor layer 2. In other words, the n-side electrode 7 and the first n-type nitride semiconductor layer 2 form an ohmic contact. Similarly, the p-side electrode 8 is electrically connected to the p-type nitride semiconductor layer 6. In other words, the p-side electrode 8 and the p-type nitride semiconductor layer 6 form an ohmic contact. The active layer 9 is interposed between the first n-type nitride semiconductor layer 2 and the p-type nitride semiconductor layer 6.

An example of the material of the n-side electrode 7 is Al or Ti. An example of the material of the p-side electrode 8 is Ag, Pt, or Ni.

(Active Layer 9)

In the first embodiment, the active layer 9 is composed of a single quantum well layer. The active layer 9 is not composed of a multi-quantum well layer. In other words, the active layer 9 consists essentially only of one nitride semiconductor layer. The single quantum well layer is formed of InGaN. Specifically, the single quantum well layer is formed of InₓGa₁₋ₓN (0<x<1). The wavelength of light emitted from the nitride semiconductor light-emitting diode may be varied depending on the value of x, which represents the composition of indium. The wavelength of the emitted light is increased with an increase in the value of x. The active layer 9 which is an n-type InGaN light-emitting layer contains silicon, carbon, or oxygen as donor impurities.

In case where the active layer 9 is composed of a multi-quantum well layer, it is meaningless to provide the nitride semiconductor light-emitting diode having the multi-quantum well structure with the second n-type nitride semiconductor layer 10, as demonstrated in the comparative example 2, which will be described later.

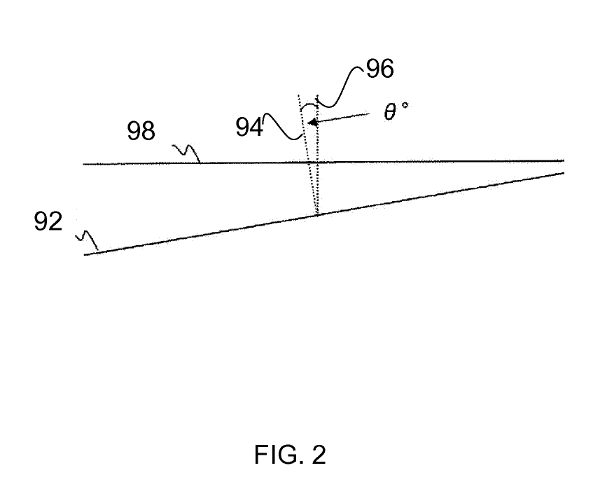

The active layer 9 has a principal surface of an m-plane having an off angle of not less than 0 degrees and not more than 15 degrees. As shown in FIG. 2, the off angle means an angle θ formed between a normal line 94 of a principal surface 92 of the active layer 9 and an m-axis 96. Needless to say, the m-axis 96 is perpendicular to an m-plane 98.

An m-plane means a (1-100) plane and planes equivalent thereto. The planes equivalent to an m-plane are a (−1010) plane, a (1-100) plane, a (−1100) plane, a (01-10) plane, and a (0-110) plane. The first n-type nitride semiconductor layer 2 and the p-type nitride semiconductor layer 6 also have a principal surface of an m-plane having an off angle of not less than 0 degrees and not more than 15 degrees. Similarly, the second n-type nitride semiconductor layer 10, which will be described later, also has a principal surface of an m-plane having an off angle of not less than 0 degrees and not more than 15 degrees. An example of the principal surface of an m-plane having an off angle of 15 degrees is a (2-20-1) plane.

Since the first n-type nitride semiconductor layer 2, the active layer 9, the second n-type nitride semiconductor layer 10, and the p-type nitride semiconductor layer 6 are epitaxially grown on the substrate 1, it is desirable that the substrate 1 may have a principal surface of an m-plane having an off angle of not less than 0 degrees and not more than 15 degrees.

Needless to say, as long as the surface of the substrate 1 has a monocrystalline nitride semiconductor layer, the material of the substrate 1 is not limited. A desirable example of the substrate 1 is a GaN substrate. The substrate 1 may be a SiC substrate having a nitride semiconductor layer grown on the surface thereof. Similarly, the substrate 1 may be a sapphire substrate having a nitride semiconductor layer grown on the surface thereof.

In case where the active layer 9 fails to have a principal surface of an m-plane having an off angle of not less than 0 degrees and not more than 15 degrees, the efficiency at a low current density is significantly decreased, even if the second n-type nitride semiconductor layer 10 is provided. See the comparative example A. In the comparative example A, the active layer has a principal surface of a c-plane.

The active layer 9 has a thickness of not less than 6 nanometers. In case where the active layer 9 has a thickness of less than 6 nanometers, the efficiency at a low current density is maintained at a high value, regardless of the presence or absence of the second n-type nitride semiconductor layer 10. Accordingly, it is meaningless to provide the second n-type nitride semiconductor layer 10. The active layer 9 having a thickness of not less than 6 nanometers (e.g., 12 nanometers) raises a problem that the efficiency at a low current density is lowered. This problem will be described later in more detail. The present embodiment solves this problem.

As is well known, the active layer 9 having a principal surface of a c-plane (hereinafter, referred to as “c-plane active layer”) has a thickness of not more than 3 nanometers. This is because the probability of the recombination of electrons and holes in the c-plane active layer is small, since the c-plane active layer has a piezoelectric field. For this reason, the thickness of the c-plane active layer is set to be a significantly small value of not more than 3 nanometers. On the other hand, the thickness of the active layer having a principal surface of an m-plane (hereinafter, referred to as “m-plane active layer”) is not limited to a value of not more than 3 nanometers. This is because the probability of the recombination of electrons and holes in the m-plane active layer is much greater than the probability in the c-plane active layer, since the m-plane active layer has no piezoelectric field.

(Second n-Type Nitride Semiconductor Layer 10 and p-Type Nitride Semiconductor Layer 6)

In the first embodiment, the second n-type nitride semiconductor layer 10 is interposed between the active layer 9 and the p-type nitride semiconductor layer 6.

In the first embodiment, either of the following requirement (A) and (B) is satisfied.

Requirement (A): the second n-type nitride semiconductor layer 10 has a donor impurity concentration of not less than 3.0×10¹⁷ cm⁻³ and less than 1.5×10¹⁸ cm⁻³, and the p-type nitride semiconductor layer 6 has an acceptor impurity concentration of not less than 5.0×10¹⁷ cm⁻³ and less than 1.0×10¹⁸ cm⁻³.

Requirement (B): the second n-type nitride semiconductor layer 10 has a donor impurity concentration of not less than 3.0×10¹⁷ cm⁻³ and not more than 2.5×10¹⁸ cm⁻³, and the p-type nitride semiconductor layer 6 has an acceptor impurity concentration of not less than 1.0×10¹⁸ cm⁻³.

In the requirement (B), it is desirable that the p-type nitride semiconductor layer 6 has an acceptor impurity concentration of not more than 2.0×10¹⁸ cm⁻³.

The degree of decrease in efficiency at a low current density is represented by the parameter of the efficiency decrease degree at a low current density (hereinafter, referred to as “ΔEQE@0.3 A/cm²”) in the instant specification. “A low efficiency at a low current density” means that the value of ΔEQE@0.3 A/cm² is not less than 0.6 in the instant specification. The term “efficiency” used in the instant specification means light-emitting efficiency of the nitride semiconductor light-emitting diode.

The efficiency decrease degree at the low current density ΔEQE@0.3 A/cm² will be described below in more detail.

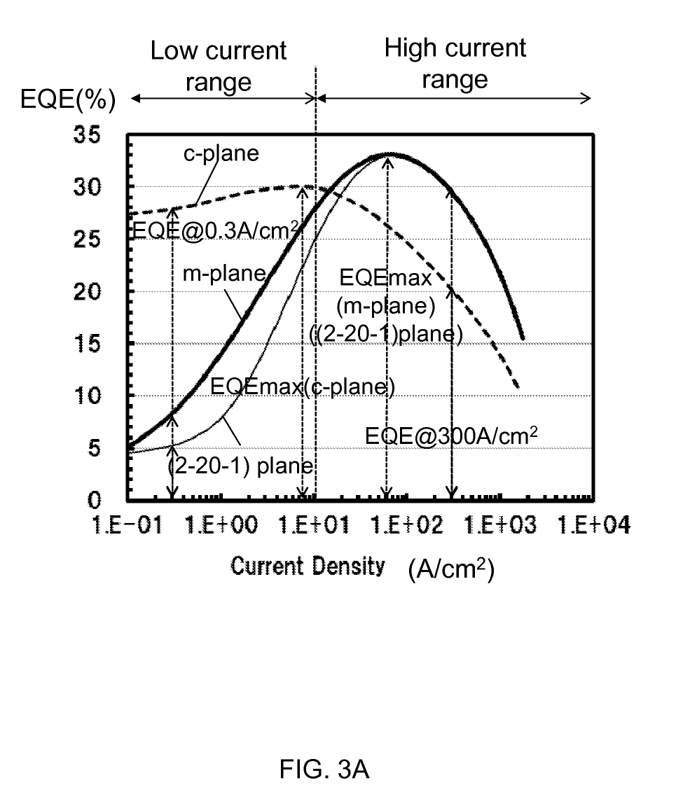

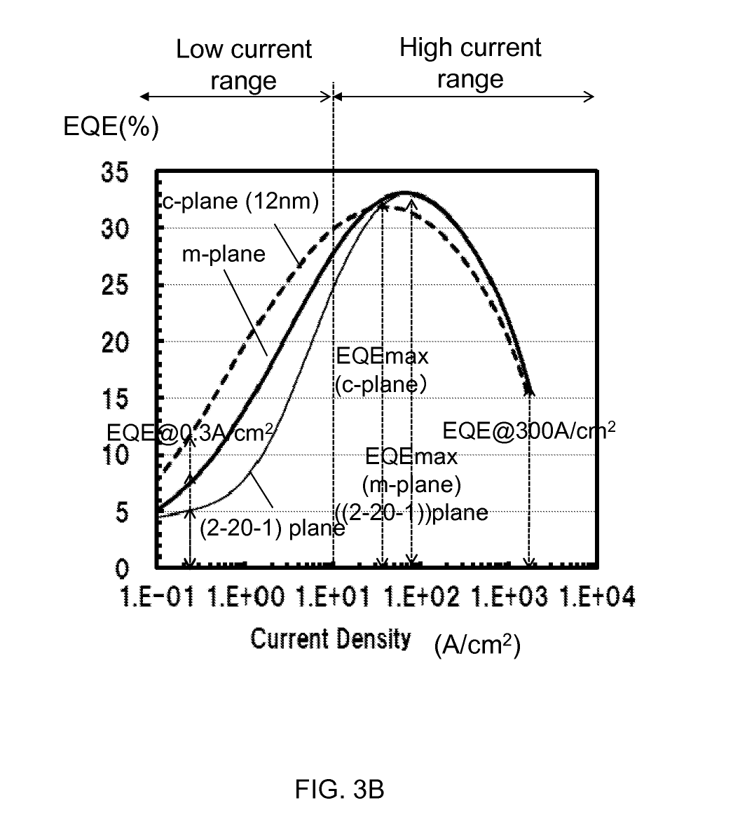

FIG. 3A is a graph showing a relation between the current density and the external quantum efficiency (hereinafter, referred to as “EQE”). The low current range means a current density from 1E-01 amperes/cm² (=0.1 amperes/cm²) to 1E−1 amperes/cm² (=10 amperes/cm²). On the other hand, the high current range means a current density from 1E−1 amperes/cm² (=10 amperes/cm²) to 1E+3 amperes/cm² (=1,000 amperes/cm²).

FIG. 3A is a graph showing the simulation results of the current density—the external quantum efficiency of three nitride semiconductor light-emitting diodes of a typical c-plane nitride semiconductor light-emitting diode, a typical m-plane nitride semiconductor light-emitting diode, and a typical (2-20-1) plane nitride semiconductor light-emitting diode. The present inventors have supposed in this simulation that the c-plane nitride semiconductor light-emitting diode, the m-plane nitride semiconductor light-emitting diode and the (2-20-1) plane nitride semiconductor light-emitting diode each comprised one layer of an InGaN light-emitting layer which is a single quantum well layer having a thicknesses of 3 nanometers, 12 nanometers, and 12 nanometers, respectively. Furthermore, the present inventors have supposed that light extraction efficiency was 60% and calculated the EQEs.

As shown in FIG. 3A, the c-plane nitride semiconductor light-emitting diode has a high EQE in the low current range. However, in the high current range, the EQE of the c-plane nitride semiconductor light-emitting diode decreases with an increase in the current density.

On the other hand, as shown in FIG. 3A, the m-plane nitride semiconductor light-emitting diode and the (2-20-1) plane nitride semiconductor light-emitting diode have higher EQEs in the high current range than the c-plane nitride semiconductor light-emitting diode, since they have thicker InGaN light-emitting layers than the c-plane nitride semiconductor light-emitting diode. However, in the low current range, the EQEs of the m-plane nitride semiconductor light-emitting diode and the (2-20-1) plane nitride semiconductor light-emitting diode are decreased significantly with a decrease in the current density. As just described, in the low current range, the m-plane nitride semiconductor light-emitting diode and the (2-20-1) plane nitride semiconductor light-emitting diode have lower EQEs than the c-plane nitride semiconductor light-emitting diode. In other words, the m-plane nitride semiconductor light-emitting diode and the (2-20-1) plane nitride semiconductor light-emitting diode have a problem that they have lower EQEs in the low current range than the c-plane nitride semiconductor light-emitting diode.

FIG. 3B shows a graph showing the simulation results of the case where a c-plane nitride semiconductor light-emitting diode comprising an InGaN light-emitting layer having a thickness of 12 nanometers is used instead of a typical c-plane nitride semiconductor light-emitting diode comprising an InGaN light-emitting layer formed of a single quantum well layer having a thickness of 3 nanometers. Note that the c-plane nitride semiconductor light-emitting diode comprising an InGaN light-emitting layer having a thickness of 12 nanometers is rare, unlike the m-plane nitride semiconductor light-emitting diode and the (2-20-1) plane nitride semiconductor light-emitting diode.

As shown in FIG. 3B, similarly to the m-plane nitride semiconductor light-emitting diode and the (2-20-1) plane nitride semiconductor light-emitting diode, the EQE of the c-plane nitride semiconductor light-emitting diode is decreased in the low current range with an increase in the thickness of the active layer 9. As just described, the nitride semiconductor light-emitting diode having a thickness of more than 3 nanometers (e.g., not less than 6 nanometers) has a problem that the EQE is low in the low current range.

In order to solve this problem, the nitride semiconductor light-emitting diode according to the first embodiment has all of the following characteristics (i)-(iv).

(i) The active layer 9 is composed of a single quantum well layer formed of n-type InGaN.

(ii) The active layer 9 has a principal surface of an m-plane having an off angle of not less than 0 degrees and not more than 15 degrees.

(iii) Either the above-mentioned requirement (A) or (B) is satisfied.

(iv) The second n-type nitride semiconductor layer 10 has a thickness not less than 25 nanometers.

These four characteristics allow the efficiency decrease degree at the low current density ΔEQE@0.3 A/cm² to be a value of not more than 0.6. In other words, the following mathematical formula (I) is satisfied.

(Efficiency Decrease Degree At The Low Current Density: ΔEQE@0.3 A/cm²)≦0.6 (I)

As understood from FIG. 3A, the efficiency decrease degree at the low current density ΔEQE@0.3 A/cm² is represented by the following mathematical formula (II).

(Efficiency Decrease Degree At The Low Current Density: ΔEQE@0.3 A/cm²)=(EQEmax−EQE@0.3 A/cm²)/EQEmax (II)

As is clear from the mathematical formula (II), the efficiency decrease degree at the low current density ΔEQE@0.3 A/cm² represents how much the EQE is decreased at the current density of 0.3 amperes/cm², which is one example of the low current density, with regard to the maximum value of the EQE (namely, EQEmax). The EQE@0.3 A/cm² means the EQE at the current density of 0.3 amperes/cm². Note that “ΔEQE@0.3 A/cm²” is distinguished clearly from “EQE@0.3 A/cm²”.

As is clear from FIG. 3A, unlike in the EQE of the c-plane nitride semiconductor light-emitting diode, the EQEs of the typical m-plane nitride semiconductor light-emitting diode and the typical (2-20-1) plane nitride semiconductor light-emitting diode are significantly decreased in the low current range with a decrease in the current density. For this reason, it is desirable that the efficiency decrease degree at the low current density ΔEQE@0.3 A/cm² is as small as possible. In other words, as is clear from the mathematical formula (II), since the efficiency decrease degree at the low current density ΔEQE@0.3 A/cm² is a value of not less than 0 and not more than 1, the closer to 0 the value of the efficiency decrease degree at the low current density ΔEQE@0.3 A/cm² is, the more desirable it is. In the nitride semiconductor light-emitting diode according to the first embodiment, the efficiency decrease degree at the low current density ΔEQE@0.3 A/cm² is not more than 0.6. It is desirable that the efficiency decrease degree at the low current density ΔEQE@0.3 A/cm² is not more than 0.5.

In the instant specification, an efficiency decrease degree at a large current density ΔEQE@300 A/cm² is defined by the following mathematical formula (III).

(Efficiency Decrease Degree At The Large Current Density ΔEQE@300 A/cm²=(EQEmax−EQE@300 A/cm²)/EQEmax (III)

The efficiency decrease degree at the large current density ΔEQE@300 A/cm² represents an EQE at a current density of 300 amperes/cm², which is one example of a large current density. The efficiency decrease degree at the large current density ΔEQE@300 A/cm² is also desirably as small as possible. Specifically, the efficiency decrease degree at the large current density ΔEQE@300 A/cm² is desirably not more than 0.20.

Next, the case will be described where any one of the characteristics (i)-(iv) fails to be satisfied.

In case where the active layer 9 is composed of a multi-quantum well layer, the efficiency decrease degree at the low current density is not varied, even if the second n-type nitride semiconductor layer 10 is provided. See the comparative example B. In the comparative example B, the active layer 9 is composed of a multi-quantum well layer. Therefore, it is meaningless to provide the nitride semiconductor light-emitting diode having a multi-quantum well layer with the second n-type nitride semiconductor layer 10.

In case where the active layer 9 fails to have a principal surface of an m-plane having an off angle of not less than 0 degrees and not more than 15 degrees, the efficiency at the low current density is not prevented from being decreased, even if the second n-type nitride semiconductor layer 10 is provided. See the comparative A. In the comparative example A, the active layer 9 has a principal surface of a c-plane. Therefore, it is meaningless to provide the nitride semiconductor light-emitting diode which does not have a principal surface of an m-plane having an off angle of not less than 0 degrees and not more than 15 degrees with the second n-type nitride semiconductor layer 10.

In case where the p-type nitride semiconductor layer 6 has an acceptor impurity concentration of less than 5.0×10¹⁷ cm⁻³ in the requirement (A), the efficiency at the low current density would not be prevented from being decreased, even if the second n-type nitride semiconductor layer 10 is provided. As understood from the comparison of Tables 2-3 to Tables 14-15, this is because the efficiency decrease degree at the low current density ΔEQE@0.3 A/cm² is increased, as the concentration of the acceptor impurities contained in the p-type nitride semiconductor layer 6 deviates from 1.0×10¹⁸ cm⁻³. For example, in both the example 1-5 and the example 6-4, each of the second n-type nitride semiconductor layers 10 has an impurity concentration of 1.0×10¹⁸ cm⁻³; however, in the example 1-5, the p-type nitride semiconductor layer 6 has an impurity concentration of 1.0×10¹⁸ cm⁻³ and the efficiency decrease degree at the low current density ΔEQE@0.3 A/cm² is 0.15. On the other hand, in the example 6-4, the p-type nitride semiconductor layer 6 has an impurity concentration of 5.0×10¹⁷ cm⁻³ and the efficiency decrease degree at the low current density ΔEQE@0.3 A/cm² is 0.33. This value is greater than the value in the example 1-5 (namely, 0.15).

In case where the second n-type nitride semiconductor layer 10 has a donor impurity concentration of less than 3.0×10¹⁷ cm⁻³ in the requirement (A), the efficiency at the low current density is not prevented from being decreased, even if the second n-type nitride semiconductor layer 10 is provided. See the comparative example 6-1.

In case where the second n-type nitride semiconductor layer 10 has a donor impurity concentration of more than 1.5×10¹⁸ cm⁻³ in the requirement (A), the efficiency at the low current density is not prevented from being decreased, even if the second n-type nitride semiconductor layer 10 is provided. See the comparative examples 6-2, 6-3, and 6-4.

In case where the second n-type nitride semiconductor layer 10 has a donor impurity concentration of less than 3.0×10¹⁷ cm⁻³ in the requirement (B), the efficiency at the low current density is not prevented from being decreased, even if the second n-type nitride semiconductor layer 10 is provided. See the comparative examples 2-4, 2-5, 7-1, and 7-2.

In case where the second n-type nitride semiconductor layer 10 has a donor impurity concentration of more than 2.5×10¹⁸ cm⁻³ in the requirement (B), the efficiency at the low current density is not prevented from being decreased, even if the second n-type nitride semiconductor layer 10 is provided. See the comparative examples 1-3 and 2-6.

In the requirement (B), it is desirable that the p-type nitride semiconductor layer 6 has an acceptor impurity concentration of not more than 2.0×10¹⁸ cm⁻³. The efficiency at the low current density would not be prevented from being decreased in a case where the p-type nitride semiconductor layer 6 has an acceptor impurity concentration of more than 2.0×10¹⁸ cm⁻³, even if the second n-type nitride semiconductor layer 10 is provided. As understood from the comparison of Tables 2-3 to Tables 16-17, this is because the efficiency decrease degree at the low current density ΔEQE@0.3 A/cm² is increased, as the concentration of the acceptor impurity contained in the p-type nitride semiconductor layer 6 deviates from 1.0×10¹⁸ cm⁻³. For example, in both the Example 1-5 and the example 7-4, the second n-type nitride semiconductor layer 10 has an impurity concentration of 1.0×10¹⁸ cm⁻³; however, in the example 1-5, the p-type nitride semiconductor layer 6 has an impurity concentration of 1.0×10¹⁸ cm⁻³ and the efficiency decrease degree at the low current density ΔEQE@0.3 A/cm² is 0.15. On the other hand, in the example 7-4, the p-type nitride semiconductor layer 6 has an impurity concentration of 2.0×10¹⁸ cm⁻³ and the efficiency decrease degree at the low current density ΔEQE@0.3 A/cm² is 0.41. This value is greater than the value in the example 1-5 (namely, 0.15).

In case where the second n-type nitride semiconductor layer 10 has a thickness of less than 25 nanometers, the efficiency at the low current density is not prevented from being decreased, even if the second n-type nitride semiconductor layer 10 is provided. See the comparative examples 3-1 and 4-1.

As just described, the second n-type nitride semiconductor layer 10 has a thickness of not less than 25 nanometers. In case where the second n-type nitride semiconductor layer 10 has a thickness of less than 25 nanometers, the efficiency is decreased at the low current density, as is clear from Tables 5 and 6, which will be described later. It is desirable that the second n-type nitride semiconductor layer 10 has a thickness of not more than 70 nanometers. More desirably, the second n-type nitride semiconductor layer 10 has a thickness of not less than 40 nanometers and not more than 70 nanometers.

Japanese Patent Application laid-open Publication No. 2002-111056A as well as Japanese Patent Application laid-open Publication No. Hei 10-200214A disclose an n-type nitride semiconductor interposed between the active layer and the p-type nitride semiconductor layer. However, these two documents fail to disclose or suggest an m-plane and a (2-20-1) plane. In light of the history of the development of the nitride semiconductor light-emitting diode, the nitride semiconductor light-emitting diodes disclosed in these two documents would have a principal surface of a c-plane, namely, a (0001) plane. Furthermore, these two documents fail to suggest the problem that an m-plane nitride semiconductor light-emitting diode and a (2-20-1) plane nitride semiconductor light-emitting diode have significantly low EQEs in the low current range. These two documents fail to suggest the problem that an active layer formed of a single quantum well layer having a thickness of more than 3 nanometers has a significantly low EQE in the low current range. Still further, these two documents fail to disclose or suggest that the characteristics (i)-(iv) prevent the efficiency at a low current density from being decreased. Therefore, even if the n-type nitride semiconductor layer is interposed between the active layer and the p-type nitride semiconductor layer in the m-plane nitride semiconductor light-emitting diode and the (2-20-1) plane nitride semiconductor light-emitting diode on the basis of these two documents, it would not be obvious to prevent the efficiency at a low current density from being decreased in the m-plane nitride semiconductor light-emitting diode and the (2-20-1) plane nitride semiconductor light-emitting diode.

### EXAMPLES

The nitride semiconductor light-emitting diode according to the first embodiment will be described in more detail with reference to the following examples and comparative examples.

The present inventors supposed that all the impurities contained in the nitride semiconductor layer were activated in the following examples and comparative examples. Actually, substantially all of the donor impurities contained in the n-type nitride semiconductor layer are activated. For this reason, the carrier concentration of the n-type nitride semiconductor layer is substantially equal to the donor impurity concentration in the n-type nitride semiconductor layer. On the other hand, not all of the acceptor impurities contained in the p-type nitride semiconductor layer are activated. Approximately 10 percent of the acceptor impurities are activated. For this reason, the carrier concentration of the p-type nitride semiconductor layer is approximately one-tenth times as much as the acceptor impurity concentration in the p-type nitride semiconductor layer.

### Example 1

Using a semiconductor simulator prophet, the effect of the second n-type nitride semiconductor layer 10 in the m-plane nitride semiconductor light-emitting element was simulated.

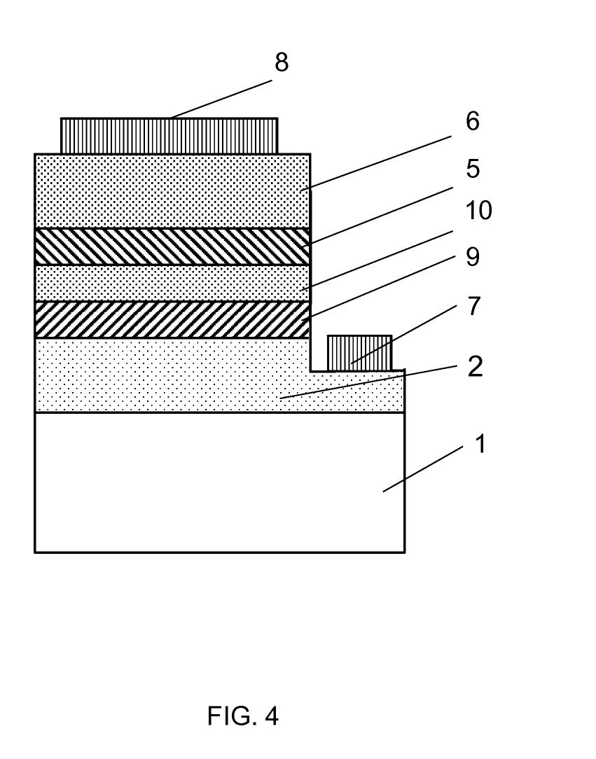

FIG. 4 shows a cross-sectional view of the m-plane nitride semiconductor light-emitting diode used in the simulation according to the example 1. Unlike in FIG. 1, the p-type nitride semiconductor layer included a first p-type nitride semiconductor layer 6 and a second p-type nitride semiconductor layer 5. In the example 1, the active layer 9 was a single quantum well layer which was an n-type InGaN layer having a thickness of 12 nanometers. The second n-type nitride semiconductor layer 10 had a thickness of 25 nanometers. In the example 1, the concentration of the donor impurities contained in the second n-type nitride semiconductor layer 10 was varied. The following Table 1 shows the thickness and the impurity concentration of the semiconductor layers included in the m-plane nitride semiconductor light-emitting diode used in the example 1. The following Table 2 and Table 3 show the results of the simulation according to the example 1.

TABLE 1

| Referential | | | | Impurity |
|---|---|---|---|---|
| Sign | Materials | Thickness | | concentration |
| 6 | p-GaN | 130 | nm | 1.0E+18 cm⁻³ |
| 5 | p-Al_{0.1}GaN_{0.9}N | 20 | nm | 1.0E+18 cm⁻³ |
| 10 | GaN | 25 | nm | (variable) |
| 9 | n-In_{0.16}Ga_{0.84}N | 12 | nm | 1.0E+17 cm⁻³ |
| 2 | n-GaN | 1000 | nm | 1.0E+18 cm⁻³ |
| 1 | n-GaN substrate | 0.1 | mm | 2.0E+18 cm⁻³ |

TABLE 2

| | | Impurity | Second n-type nitride | | | | |
|---|---|---|---|---|---|---|---|
| | | concentration | semiconductor layer 10 | | | n-type InGaN | |
| | | of p-type | | Impurity | | active layer 9 | |
| | Plane | GaN | Polar- | concentration | Thickness | Polar- | Thickness |
| | Direction | layer 6 | ity | [cm⁻³] | [nm] | ity | [nm] |
| Comparative | m-plane | 1.0E+18 | p | 5.0E+17 | 25 | n | 12 |
| example 1-1 | | | | | | | |
| Comparative | | | | 2.5E+17 | | | |
| example 1-2 | | | | | | | |
| Reference | | | n | 1.0E+17 | | | |
| example 1-1 | | | | | | | |
| Reference | | | | 2.0E+17 | | | |
| example 1-2 | | | | | | | |
| Example 1-1 | | | | 3.0E+17 | | | |
| Example 1-2 | | | | 4.0E+17 | | | |
| Example 1-3 | | | | 5.0E+17 | | | |
| Example 1-4 | | | | 8.0E+17 | | | |
| Example 1-5 | | | | 1.0E+18 | | | |
| Example 1-6 | | | | 1.5E+18 | | | |
| Example 1-7 | | | | 2.0E+18 | | | |
| Example 1-8 | | | | 2.2E+18 | | | |
| Example 1-9 | | | | 2.4E+18 | | | |
| Example 1-10 | | | | 2.5E+18 | | | |
| Comparative | | | | 3.0E+18 | | | |
| example 1-3 | | | | | | | |

TABLE 3

| | | | | Efficiency decrease | Efficiency decrease |
|---|---|---|---|---|---|
| | | Low current | Large current | degree at the low | degree at the large |
| | | density | density | current density | current density |
| | EQE | EQE@0.3 | EQE@300 | ΔEQE@0.3 | ΔEQE@300 |
| | max | A/cm² | A/cm² | A/cm² | A/cm² |
| Comparative | 33.1 | 7.5 | 29.8 | 0.77 | 0.10 |
| example 1-1 | | | | | |
| Comparative | 33.1 | 7.8 | 29.9 | 0.76 | 0.10 |
| example 1-2 | | | | | |
| Reference | 33.1 | 12.2 | 29.9 | 0.63 | 0.10 |
| example 1-1 | | | | | |
| Reference | 33.1 | 14.4 | 29.9 | 0.56 | 0.10 |
| example 1-2 | | | | | |
| Example 1-1 | 33.1 | 16.8 | 29.9 | 0.49 | 0.10 |
| Example 1-2 | 33.0 | 19.2 | 29.8 | 0.42 | 0.10 |
| Example 1-3 | 33.0 | 21.4 | 29.8 | 0.35 | 0.10 |
| Example 1-4 | 33.1 | 26.1 | 29.7 | 0.21 | 0.10 |
| Example 1-5 | 33.0 | 28.0 | 29.5 | 0.15 | 0.11 |
| Example 1-6 | 31.1 | 27.9 | 27.6 | 0.10 | 0.11 |
| Example 1-7 | 25.8 | 19.6 | 23.8 | 0.24 | 0.08 |
| Example 1-8 | 23.2 | 15.5 | 22.0 | 0.33 | 0.05 |
| Example 1-9 | 20.8 | 12.0 | 20.0 | 0.42 | 0.04 |
| Example 1-10 | 19.5 | 10.4 | 19.0 | 0.46 | 0.03 |
| Comparative | 13.7 | 5.1 | 13.6 | 0.63 | 0.00 |
| example 1-3 | | | | | |

As is clear from the examples 1-1-1-10 shown in Tables 2-3, if all the following requirements are satisfied, the value of the efficiency decrease degree at the low current density ΔEQE@0.3 A/cm² is not more than 0.5.

(a) The nitride semiconductor layer 10 is n-type.

(b) The second n-type nitride semiconductor layer 10 has an impurity concentration of not less than 3.0E+17 cm⁻³ and not more than 2.5E+18 cm⁻³.

If the second n-type nitride semiconductor layer 10 has an impurity concentration of not less than 2.0E−17 cm⁻³ and less than 3.0E−17 cm⁻³, see Table 5 and Table 6, which will be described later.

In case where the nitride semiconductor layer 10 is p-type, the value of the efficiency decrease degree at the low current density ΔEQE@0.3 A/cm² is a large value of not less than 0.76. See the comparative examples 1-1 and 1-2. Note that the nitride semiconductor light-emitting diodes according to the comparative examples 1-1 and 1-2 are typical nitride semiconductor light-emitting diodes each having a stacked structure of an n-type nitride semiconductor layer/an active layer/a p-type nitride semiconductor layer, since the nitride semiconductor layers 10 thereof are p-type. In case where the second n-type nitride semiconductor layer 10 has an impurity concentration of more than 2.5E+18 cm⁻³, the value of the efficiency decrease degree at the low current density ΔEQE@0.3 A/cm² is a large value of 0.63. See the comparative example 1-3.

When the second n-type nitride semiconductor layer 10 has an impurity concentration of not less than 5.0×10¹⁷ cm⁻³ and not more than 2.2×10¹⁸ cm⁻³, the value of the efficiency decrease degree at the low current density ΔEQE@0.3 A/cm² is a small value of not more than 0.35. See the examples 1-3-1-8.

In the example 1, the value of the efficiency decrease degree at the high current density ΔEQE@300 A/cm² is a small value of not more than 0.11.

### Example 2

Similarly to the case of the example 1, using a semiconductor simulator prophet, the effect of the second n-type nitride semiconductor layer 10 in the m-plane nitride semiconductor light-emitting element was simulated. The nitride semiconductor light-emitting diode according to the example 2 was same as the nitride semiconductor light-emitting diode according to the example 1, except that the nitride semiconductor light-emitting diode according to the example 2 had a principal surface of an m-plane having an off angle of 15 degrees. In other words, the nitride semiconductor light-emitting diode according to the example 2 had a principal surface of a (2-20-1) plane.

The following Table 4 and Table 5 show the results of the simulation according to the example 2.

TABLE 4

| | | Impurity | Second n-type nitride | | | | |
|---|---|---|---|---|---|---|---|
| | | concentration | semiconductor layer 10 | | | n-type InGaN | |
| | | of p-type | | Impurity | | active layer 9 | |
| | Plane | GaN | Polar- | concentration | Thickness | Polar- | Thickness |
| | direction | layer 6 | ity | [cm⁻³] | [nm] | ity | [nm] |
| Comparative | 15 | 1.0E+18 | p | 5.0E+17 | 25 | n | 12 |
| example 2-1 | degrees | | | | | | |
| Comparative | | | | 2.5E+17 | | | |
| example 2-2 | | | | | | | |
| Comparative | | | | 1.0E+17 | | | |
| example 2-3 | | | | | | | |
| Comparative | | | n | 1.0E+17 | | | |
| example 2-4 | | | | | | | |
| Comparative | | | | 2.0E+17 | | | |
| example 2-5 | | | | | | | |
| Example 2-1 | | | | 3.0E+17 | | | |
| Example 2-2 | | | | 4.0E+17 | | | |
| Example 2-3 | | | | 5.0E+17 | | | |
| Example 2-4 | | | | 8.0E+17 | | | |
| Example 2-5 | | | | 1.0E+18 | | | |
| Example 2-6 | | | | 1.2E+18 | | | |
| Example 2-7 | | | | 1.5E+18 | | | |
| Example 2-8 | | | | 1.7E+18 | | | |
| Example 2-9 | | | | 2.0E+18 | | | |
| Example 2-10 | | | | 2.2E+18 | | | |
| Example 2-11 | | | | 2.4E+18 | | | |
| Example 2-12 | | | | 2.5E+18 | | | |
| Comparative | | | | 3.0E+18 | | | |
| example 2-6 | | | | | | | |

TABLE 5

| | | | | Efficiency decrease | Efficiency decrease |
|---|---|---|---|---|---|
| | | Low current | Large current | degree at the low | degree at the large |
| | | density | density | current density | current density |
| | EQE | EQE@0.3 | EQE@300 | ΔEQE@0.3 | ΔEQE@300 |
| | max | A/cm² | A/cm² | A/cm² | A/cm² |
| Comparative | 33.1 | 2.6 | 30.1 | 0.92 | 0.09 |
| example 2-1 | | | | | |
| Comparative | 33.1 | 5.2 | 30.0 | 0.84 | 0.09 |
| example 2-2 | | | | | |
| Comparative | 33.1 | 7.2 | 30.0 | 0.78 | 0.09 |
| example 2-3 | | | | | |
| Comparative | 33.1 | 11.0 | 30.0 | 0.67 | 0.09 |
| example 2-4 | | | | | |
| Comparative | 33.1 | 12.7 | 30.0 | 0.62 | 0.09 |
| example 2-5 | | | | | |
| Example 2-1 | 33.1 | 14.2 | 30.0 | 0.57 | 0.09 |
| Example 2-2 | 33.1 | 15.5 | 29.9 | 0.53 | 0.10 |
| Example 2-3 | 33.1 | 16.6 | 29.9 | 0.50 | 0.10 |
| Example 2-4 | 33.0 | 19.1 | 29.7 | 0.42 | 0.10 |
| Example 2-5 | 33.0 | 20.3 | 29.5 | 0.38 | 0.11 |
| Example 2-6 | 32.5 | 21.0 | 28.9 | 0.35 | 0.11 |
| Example 2-7 | 30.7 | 20.0 | 27.4 | 0.35 | 0.11 |
| Example 2-8 | 28.9 | 18.0 | 25.9 | 0.38 | 0.10 |
| Example 2-9 | 25.2 | 13.9 | 23.1 | 0.45 | 0.08 |
| Example 2-10 | 22.5 | 11.1 | 21.0 | 0.50 | 0.06 |
| Example 2-11 | 19.7 | 8.6 | 18.9 | 0.56 | 0.04 |
| Example 2-12 | 18.4 | 7.6 | 17.8 | 0.59 | 0.03 |
| Comparative | 12.5 | 3.7 | 12.5 | 0.70 | 0.00 |
| example 2-6 | | | | | |

As is clear from the examples 2-1-2-12 shown in Tables 4-5, if all the following requirements are satisfied, the value of the efficiency decrease degree at the low current density ΔEQE@0.3 A/cm² is not more than 0.5.

(a) The nitride semiconductor layer 10 is n-type.

(b) The second n-type nitride semiconductor layer 10 has an impurity concentration of not less than 3.0E+17 cm⁻³ and not more than 2.5E+18 cm⁻³.

In case where the nitride semiconductor layer 10 is p-type, the value of the efficiency decrease degree at the low current density ΔEQE@0.3 A/cm² is a large value of not less than 0.78. See the comparative examples 2-1-2-3. Note that the nitride semiconductor light-emitting diodes according to the comparative examples 2-1 and 2-2 are typical nitride semiconductor light-emitting diodes each having a stacked structure of an n-type nitride semiconductor layer/an active layer/a p-type nitride semiconductor layer, since the nitride semiconductor layers 10 thereof are p-type. In case where the second n-type nitride semiconductor layer 10 has an impurity concentration of less than 3.0E+17 cm⁻³, the value of the efficiency decrease degree at the low current density ΔEQE@0.3 A/cm² is a large value of not less than 0.62. See the comparative examples 2-4 and 2-5. In case where the second n-type nitride semiconductor layer 10 has an impurity concentration of more than 2.5E+18 cm⁻³, the value of the efficiency decrease degree at the low current density ΔEQE@0.3 A/cm² is a large value of 0.70. See the comparative example 2-6.

When the second n-type nitride semiconductor layer 10 has an impurity concentration of not less than 1.2E+18 cm⁻³ and not more than 1.5E+18 cm⁻³, the value of the efficiency decrease degree at the low current density ΔEQE@0.3 A/cm² is a small value of not more than 0.35. See the examples 2-6-2-7.

Also in the example 2, the value of the efficiency decrease degree at the high current density ΔEQE@300 A/cm² is a small value of not more than 0.11.

### Example 3

Using a semiconductor simulator prophet, the effect of the second n-type semiconductor layer 10 in the m-plane nitride semiconductor light-emitting element was simulated.

In the example 3, the active layer 9 was a single quantum well layer formed of an n-type InGaN layer having a thickness of 12 nanometers. In the example 3, the thickness of the second n-type nitride semiconductor layer 10 was varied. In the example 3, the concentration of the donor impurities contained in the second n-type nitride semiconductor layer 10 was maintained at 5.0E−17 cm⁻³. The following Table 6 shows the thickness and the impurity concentration of the semiconductor layers included in the m-plane nitride semiconductor light-emitting diode used in the example 3. The following Table 7 and Table 8 show the results of the simulation according to the example 3.

TABLE 6

| Referential | | | | Impurity |
|---|---|---|---|---|
| Sign | Materials | Thickness | | concentration |
| 6 | p-GaN | 130 | nm | 1.0E+18 cm⁻³ |
| 5 | p-Al_{0.1}GaN_{0.9}N | 20 | nm | 1.0E+18 cm⁻³ |
| 10 | GaN | (variable) | | 5.0E+17 cm⁻³ |
| 9 | n-In_{0.16}Ga_{0.84}N | 12 | nm | 1.0E+17 cm⁻³ |
| 2 | n-GaN | 1000 | nm | 1.0E+18 cm⁻³ |
| 1 | n-GaN substrate | 0.1 | mm | 2.0E+18 cm⁻³ |

TABLE 7

| | | Impurity | Second n-type nitride | | | | |
|---|---|---|---|---|---|---|---|
| | | concentration | semiconductor layer 10 | | | n-type InGaN | |
| | | of p-type | | Impurity | | active layer 9 | |
| | Plane | GaN | Polar- | concentration | Thickness | Polar- | Thickness |
| | direction | layer 6 | ity | [cm⁻³] | [nm] | ity | [nm] |
| Comparative | m-plane | 1.0E+18 | n | 5.0E+17 | 10 | n | 12 |
| example 3-1 | | | | | | | |
| Example 3-1 | | | | | 25 | | |
| Example 3-2 | | | | | 40 | | |
| Example 3-3 | | | | | 55 | | |
| Example 3-4 | | | | | 70 | | |

TABLE 8

| | | | | Efficiency decrease | Efficiency decrease |
|---|---|---|---|---|---|
| | | Low current | Large current | degree at the low | degree at the large |
| | | density | density | current density | current density |
| | EQE | EQE@0.3 | EQE@300 | ΔEQE@0.3 | ΔEQE@300 |
| | max | A/cm² | A/cm² | A/cm² | A/cm² |
| Comparative | 33.1 | 10.6 | 29.9 | 0.63 | 0.10 |
| example 3-1 | | | | | |
| Example 3-1 | 33.0 | 21.4 | 29.8 | 0.35 | 0.10 |
| Example 3-2 | 33.0 | 26.5 | 29.6 | 0.20 | 0.10 |
| Example 3-3 | 32.9 | 27.8 | 29.4 | 0.15 | 0.10 |
| Example 3-4 | 32.7 | 27.5 | 29.3 | 0.16 | 0.10 |

As is clear from the examples 3-1-3-4 shown in Tables 7-8, if the following requirement is satisfied, the value of the efficiency decrease degree at the low current density ΔEQE@0.3 A/cm² is not more than 0.5.

(c) The second n-type nitride semiconductor layer 10 has a thickness of not less than 25 nanometers.

In case where the second n-type nitride semiconductor layer 10 has a thickness of less than 25 nanometers, the value of the efficiency decrease degree at the low current density ΔEQE@0.3 A/cm² is a large value of 0.63. See the comparative example 3-1.

Also in the example 3, the value of the efficiency decrease degree at the large current density ΔEQE@300 A/cm² is a small value of not more than 0.10.

### Example 4

Similarly to the example 1, using a semiconductor simulator prophet, the effect of the second n-type nitride semiconductor layer 10 in the m-plane nitride semiconductor light-emitting element was simulated. The nitride semiconductor light-emitting diode according to the example 4 was same as the nitride semiconductor light-emitting diode according to the example 3, except that the nitride semiconductor light-emitting diode according to the example 4 had a principal surface of an m-plane having an off angle of 15 degrees. In other words, the nitride semiconductor light-emitting diode according to the example 4 had a principal surface of a (2-20-1) plane.

The following Table 9 and Table 10 show the results of the simulation according to the example 4.

TABLE 9

| | | Impurity | Second n-type nitride | | | | |
|---|---|---|---|---|---|---|---|
| | | concentration | semiconductor layer 10 | | | n-type InGaN | |
| | | of p-type | | Impurity | | active layer 9 | |
| | Plane | GaN | Polar- | concentration | Thickness | Polar- | Thickness |
| | direction | layer 6 | ity | [cm⁻³] | [nm] | ity | [nm] |
| Comparative | 15 | 1.0E+18 | n | 5.0E+17 | 10 | n | 12 |
| example 4-1 | degrees | | | | | | |
| Example 4-1 | | | | | 25 | | |
| Example 4-2 | | | | | 40 | | |
| Example 4-3 | | | | | 55 | | |
| Example 4-4 | | | | | 70 | | |

TABLE 10

| | | | | Efficiency decrease | Efficiency decrease |
|---|---|---|---|---|---|
| | | Low current | Large current | degree at the low | degree at the large |
| | | density | density | current density | current density |
| | EQE | EQE@0.3 | EQE@300 | ΔEQE@0.3 | ΔEQE@300 |
| | max | A/cm² | A/cm² | A/cm² | A/cm² |
| Comparative | 33.1 | 9.8 | 30.0 | 0.70 | 0.09 |
| example 4-1 | | | | | |
| Example 4-1 | 33.1 | 16.6 | 29.9 | 0.50 | 0.10 |
| Example 4-2 | 33.0 | 19.4 | 29.7 | 0.41 | 0.10 |
| Example 4-3 | 32.7 | 20.0 | 29.5 | 0.39 | 0.10 |
| Example 4-4 | 32.7 | 19.8 | 29.3 | 0.39 | 0.10 |

As is clear from the examples 4-1-4-4 shown in Tables 9-10, if the following requirement is satisfied, the value of the efficiency decrease degree at the low current density ΔEQE@0.3 A/cm² is not more than 0.5.

(c) The second n-type nitride semiconductor layer 10 has a thickness of not less than 25 nanometers.

In case where the second n-type nitride semiconductor layer 10 has a thickness of less than 25 nanometers, the value of the efficiency decrease degree at the low current density ΔEQE@0.3 A/cm² is a large value of 0.70. See the comparative example 4-1.

Also in the example 4, the value of the efficiency decrease degree at the high current density ΔEQE@300 A/cm² is a small value of not more than 0.10.

### Example 5

Using a semiconductor simulator prophet, the effect of the second n-type semiconductor layer 10 in the m-plane nitride semiconductor light-emitting element was simulated.

In the example 5, the thickness of the active layer 9 was varied. The active layer 9 was a single quantum well layer formed of an n-type InGaN layer. In the example 5, the second n-type nitride semiconductor layer 10 had a thickness of 70 nanometers. In the example 5, the concentration of the donor impurities contained in the second n-type nitride semiconductor layer 10 was maintained at 2.0E+17 cm⁻³. The following Table 11 shows the thickness and the impurity concentration of the semiconductor layers included in the m-plane nitride semiconductor light-emitting diode used in the example 5. The following Table 12 and Table 13 show the results of the simulation according to the example 5.

TABLE 11

| Referential | | | | Impurity |
|---|---|---|---|---|
| Sign | Materials | Thickness | | concentration |
| 6 | p-GaN | 130 | nm | 1.0E+18 cm⁻³ |
| 5 | p-Al_{0.1}GaN_{0.9}N | 20 | nm | 1.0E+18 cm⁻³ |
| 10 | GaN | 70 | nm | 2.0E+17 cm⁻³ |
| 9 | n-In_{0.16}Ga_{0.84}N | (variable) | | 1.0E+17 cm⁻³ |
| 2 | n-GaN | 1000 | nm | 1.0E+18 cm⁻³ |
| 1 | n-GaN substrate | 0.1 | mm | 2.0E+18 cm⁻³ |

TABLE 12

| | | Impurity | Second n-type nitride | | | | |
|---|---|---|---|---|---|---|---|
| | | concentration | semiconductor layer 10 | | | n-type InGaN | |
| | | of p-type | | Impurity | | active layer 9 | |
| | Plane | GaN | Polar- | concentration | Thickness | Polar- | Thickness |
| | direction | layer 6 | ity | [cm⁻³] | [nm] | ity | [nm] |
| Reference | m-plane | 1.0E+18 | n | 2.0E+17 | 70 | n | 3 |
| example 5-1 | | | | | | | |
| Example 5-1 | | | | | | | 6 |
| Example 5-2 | | | | | | | 9 |
| Example 5-3 | | | | | | | 12 |
| Example 5-4 | | | | | | | 15 |
| Example 5-5 | | | | | | | 18 |
| Example 5-6 | | | | | | | 24 |
| Example 5-7 | | | | | | | 30 |
| Example 5-8 | | | | | | | 35 |
| Example 5-9 | | | | | | | 40 |

TABLE 13

| | | | | Efficiency decrease | Efficiency decrease |
|---|---|---|---|---|---|
| | | Low current | Large current | degree at the low | degree at the large |
| | | density | density | current density | current density |
| | EQE | EQE@0.3 | EQE@300 | ΔEQE@0.3 | ΔEQE@300 |
| | max | A/cm² | A/cm² | A/cm² | A/cm² |
| Reference | 32.6 | 32.0 | 23.2 | 0.02 | 0.29 |
| example 5-1 | | | | | |
| Example 5-1 | 33.0 | 32.8 | 26.7 | 0.01 | 0.19 |
| Example 5-2 | 32.9 | 29.7 | 28.5 | 0.10 | 0.13 |
| Example 5-3 | 32.7 | 27.4 | 29.5 | 0.16 | 0.10 |
| Example 5-4 | 32.5 | 25.9 | 30.1 | 0.20 | 0.08 |
| Example 5-5 | 32.4 | 23.4 | 30.5 | 0.28 | 0.06 |
| Example 5-6 | 32.1 | 19.3 | 31.0 | 0.40 | 0.03 |
| Example 5-7 | 31.7 | 16.7 | 31.1 | 0.47 | 0.02 |
| Example 5-8 | 31.5 | 15.2 | 31.1 | 0.52 | 0.01 |
| Example 5-9 | 31.2 | 14.0 | 31.0 | 0.55 | 0.01 |

As is clear from the examples 5-1-5-9 and the reference example 5-1 shown in Tables 12-13, the value of the efficiency decrease degree at the low current density ΔEQE@0.3 A/cm² is decreased with a decrease in the thickness of the active layer 9. On the other hand, the value of the efficiency decrease degree at the large current density ΔEQE@300 A/cm² is increased with a decrease in the thickness of the active layer 9. If the active layer 9 has a thickness of not less than 6 nanometers and not more than 15 nanometers, both of the values of the efficiency decrease degree at the low current density ΔEQE@0.3 A/cm² and the efficiency decrease degree at the large current density ΔEQE@300 A/cm² are not more than 0.20.

### Example 6

Using a semiconductor simulator prophet, the effect of the second n-type nitride semiconductor layer 10 in the m-plane nitride semiconductor light-emitting element was simulated.

In the example 6, a simulation similar to that of the example 2 was conducted, except that the acceptor impurity concentration of the p-type nitride semiconductor layer 6 was maintained at 5.0E+17 cm⁻³. The following Table 14 and Table 15 show the results of the simulation according to the example 6.

TABLE 14

| | | Impurity | Second n-type nitride | | | | |
|---|---|---|---|---|---|---|---|
| | | concentration | semiconductor layer 10 | | | n-type InGaN | |
| | | of p-type | | Impurity | | active layer 9 | |
| | Plane | GaN | Polar- | concentration | Thickness | Polar- | Thickness |
| | direction | layer 6 | ity | [cm⁻³] | [nm] | ity | [nm] |
| Comparative | 15 | 5.0E+17 | n | 1.0E+17 | 25 | n | 12 |
| example 6-1 | degrees | | | | | | |
| Reference | | | | 2.0E+17 | | | |
| example 6-1 | | | | | | | |
| Example 6-1 | | | | 3.0E+17 | | | |
| Example 6-2 | | | | 5.0E+17 | | | |
| Example 6-3 | | | | 8.0E+17 | | | |
| Example 6-4 | | | | 1.0E+18 | | | |
| Example 6-5 | | | | 1.2E+18 | | | |
| Example 6-6 | | | | 1.5E+18 | | | |
| Comparative | | | | 2.0E+18 | | | |
| example 6-2 | | | | | | | |
| Comparative | | | | 2.5E+18 | | | |
| example 6-3 | | | | | | | |
| Comparative | | | | 3.0E+18 | | | |
| example 6-4 | | | | | | | |

TABLE 15

| | | | | Efficiency decrease | Efficiency decrease |
|---|---|---|---|---|---|
| | | Low current | Large current | degree at the low | degree at the large |
| | | density | density | current density | current density |
| | EQE | EQE@0.3 | EQE@300 | ΔEQE@0.3 | ΔEQE@300 |
| | Max | A/cm² | A/cm² | A/cm² | A/cm² |
| Comparative | 33.1 | 12.43 | 30.00 | 0.62 | 0.09 |
| example 6-1 | | | | | |
| Reference | 33.1 | 14.18 | 29.98 | 0.57 | 0.09 |
| example 6-1 | | | | | |
| Example 6-1 | 33.1 | 15.61 | 29.94 | 0.53 | 0.10 |
| Example 6-2 | 33.1 | 17.79 | 29.84 | 0.46 | 0.10 |
| Example 6-3 | 32.9 | 19.96 | 29.16 | 0.39 | 0.11 |
| Example 6-4 | 30.6 | 20.39 | 27.11 | 0.33 | 0.11 |
| Example 6-5 | 26.3 | 16.43 | 24.53 | 0.38 | 0.07 |
| Example 6-6 | 20.7 | 8.18 | 20.32 | 0.60 | 0.02 |
| Comparative | 12.3 | 2.29 | 12.21 | 0.81 | 0.00 |
| example 6-2 | | | | | |
| Comparative | 6.2 | 0.77 | 5.86 | 0.88 | 0.06 |
| example 6-3 | | | | | |
| Comparative | 3.0 | 0.32 | 2.54 | 0.89 | 0.14 |
| example 6-4 | | | | | |

As is clear from the examples 6-1-6-6 shown in Tables 14-15, if the p-type nitride semiconductor layer 6 has an acceptor impurity concentration of 5.0×10¹⁷ cm⁻³, the upper limit of the concentration of the donor impurity contained in the second n-type nitride semiconductor layer 10 is 1.5×10¹⁸ cm⁻³. If the second n-type nitride semiconductor layer 10 has a donor impurity concentration of more than 1.5×10¹⁸ cm⁻³, the value of the efficiency decrease degree at the low current density ΔEQE@0.3 A/cm² is increased. On the other hand, also if the second n-type nitride semiconductor layer 10 has a donor impurity concentration of less than 2.0×10¹⁷ cm⁻³, the value of the efficiency decrease degree at the low current density ΔEQE@0.30A/cm² is increased.

Also in the example 6, the efficiency decrease degree at the large current density ΔEQE@300 A/cm² was a small value of not more than 0.11.

### Example 7

Using a semiconductor simulator prophet, the effect of the second n-type semiconductor layer 10 in the m-plane nitride semiconductor light-emitting element was simulated.

In the example 7, a simulation similar to the simulation according to the example 2 was conducted, except that the acceptor impurity concentration of the p-type nitride semiconductor layer 6 was maintained at 2.0E+18 cm⁻³. The following Table 16 and Table 17 show the results of the simulation according to the example 7.

TABLE 16

| | | Impurity | Second n-type nitride | | | | |
|---|---|---|---|---|---|---|---|
| | | concentration | semiconductor layer 10 | | | n-type InGaN | |
| | | of p-type | | Impurity | | active layer 9 | |
| | Plane | GaN | Polar- | concentration | Thickness | Polar- | Thickness |
| | direction | layer 6 | ity | [cm⁻³] | [nm] | ity | [nm] |
| Comparative | 15 | 2.0E+18 | n | 1.0E+17 | 25 | n | 12 |
| example 7-1 | degrees | | | | | | |
| Comparative | | | | 2.0E+17 | | | |
| example 7-2 | | | | | | | |
| Example 7-1 | | | | 3.0E+17 | | | |
| Example 7-2 | | | | 5.0E+17 | | | |
| Example 7-3 | | | | 8.0E+17 | | | |
| Example 7-4 | | | | 1.0E+18 | | | |
| Example 7-5 | | | | 1.5E+18 | | | |
| Example 7-6 | | | | 2.0E+18 | | | |
| Example 7-7 | | | | 2.5E+18 | | | |
| Reference | | | | 3.0E+18 | | | |
| example 7-1 | | | | | | | |
| Reference | | | | 4.0E+18 | | | |
| example 7-2 | | | | | | | |

TABLE 17

| | | | | Efficiency decrease | Efficiency decrease |
|---|---|---|---|---|---|
| | | Low current | Large current | degree at the low | degree at the large |
| | | density | density | current density | current density |
| | EQE | EQE@0.3 | EQE@300 | ΔEQE@0.3 | ΔEQE@300 |
| | max | A/cm² | A/cm² | A/cm² | A/cm² |
| Comparative | 33.1 | 10.25 | 30.02 | 0.69 | 0.09 |
| example 7-1 | | | | | |
| Comparative | 33.1 | 11.84 | 30.01 | 0.64 | 0.09 |
| example 7-2 | | | | | |
| Example 7-1 | 33.1 | 13.24 | 29.99 | 0.60 | 0.09 |
| Example 7-2 | 33.1 | 15.54 | 29.94 | 0.53 | 0.10 |
| Example 7-3 | 33.1 | 18.14 | 29.79 | 0.45 | 0.10 |
| Example 7-4 | 33.0 | 19.44 | 29.65 | 0.41 | 0.10 |
| Example 7-5 | 32.8 | 21.33 | 29.18 | 0.35 | 0.11 |
| Example 7-6 | 31.8 | 21.06 | 28.18 | 0.34 | 0.11 |
| Example 7-7 | 29.7 | 19.63 | 26.29 | 0.34 | 0.12 |
| Reference | 26.5 | 16.93 | 23.47 | 0.36 | 0.11 |
| example 7-1 | | | | | |
| Reference | 17.7 | 9.95 | 16.28 | 0.44 | 0.08 |
| example 7-2 | | | | | |

As is clear from the examples 7-1-7-7 shown in Tables 16-17, even if the p-type nitride semiconductor layer 6 has an acceptor impurity concentration of 2.0×10¹⁸ cm⁻³, the effect similar to that of the example 2 is obtained.

Also in the example 7, the efficiency decrease degree at the large current density ΔEQE@300 A/cm² was a small value of not more than 0.12.

### Comparative Example A

In the comparative example A, a simulation similar to that of the example 1 was conducted, except that a c-plane nitride semiconductor was used instead of the m-plane nitride semiconductor. In other words, the nitride semiconductor light-emitting diode according to the comparative example A had a principal surface of a (0001) plane. Table 18 and Table 19 show the results of the simulation according to the comparative example A.

TABLE 18

| | | Impurity | Second n-type nitride | | | | |
|---|---|---|---|---|---|---|---|
| | | concentration | semiconductor layer 10 | | | n-type InGaN | |
| | | of p-type | | Impurity | | active layer 9 | |
| | Plane | GaN | Polar- | concentration | Thickness | Polar- | Thickness |
| | direction | layer 6 | ity | [cm⁻³] | [nm] | ity | [nm] |
| Comparative | c-plane | 1.0E+18 | p | 3.0E+18 | 25 | n | 12 |
| example A-1 | | | | | | | |
| Comparative | | | | 2.5E+17 | | | |
| example A-2 | | | | | | | |
| Comparative | | | | 2.0E+18 | | | |
| example A-3 | | | | | | | |
| Comparative | | | | 1.5E+18 | | | |
| example A-4 | | | | | | | |
| Comparative | | | | 1.0E+18 | | | |
| example A-5 | | | | | | | |
| Comparative | | | | 5.0E+17 | | | |
| example A-6 | | | | | | | |
| Comparative | | | | 2.0E+17 | | | |
| example A-7 | | | | | | | |
| Comparative | | | n | 1.0E+17 | | | |
| example A-8 | | | | | | | |
| Comparative | | | | 2.0E+17 | | | |
| example A-9 | | | | | | | |
| Comparative | | | | 5.0E+17 | | | |
| example A-10 | | | | | | | |
| Comparative | | | | 8.0E+17 | | | |
| example A-11 | | | | | | | |
| Comparative | | | | 1.0E+18 | | | |
| example A-12 | | | | | | | |

TABLE 18

| | | | | Efficiency decrease | Efficiency decrease |
|---|---|---|---|---|---|
| | | Low current | Large current | degree at the low | degree at the large |
| | | density | density | current density | current density |
| | EQE | EQE@0.3 | EQE@300 | ΔEQE@0.3 | ΔEQE@300 |
| | max | A/cm² | A/cm² | A/cm² | A/cm² |
| Comparative | 32.0 | 9.2 | 28.2 | 0.71 | 0.12 |
| example A-1 | | | | | |
| Comparative | 32.0 | 8.6 | 28.1 | 0.73 | 0.12 |
| example A-2 | | | | | |
| Comparative | 32.0 | 9.1 | 28.1 | 0.71 | 0.12 |
| example A-3 | | | | | |
| Comparative | 31.9 | 10.2 | 28.0 | 0.68 | 0.12 |
| example A-4 | | | | | |
| Comparative | 31.9 | 11.1 | 27.9 | 0.65 | 0.13 |
| example A-5 | | | | | |
| Comparative | 31.8 | 11.8 | 27.8 | 0.63 | 0.13 |
| example A-6 | | | | | |
| Comparative | 31.8 | 12.1 | 27.7 | 0.62 | 0.13 |
| example A-7 | | | | | |
| Comparative | 31.7 | 11.8 | 27.6 | 0.63 | 0.13 |
| example A-8 | | | | | |
| Comparative | 31.8 | 11.4 | 27.6 | 0.64 | 0.13 |
| example A-9 | | | | | |
| Comparative | 31.7 | 11.5 | 27.4 | 0.64 | 0.14 |
| example A-10 | | | | | |
| Comparative | 31.8 | 12.15 | 27.4 | 0.62 | 0.14 |
| example A-11 | | | | | |
| Comparative | 31.7 | 12.18 | 27.3 | 0.62 | 0.14 |
| example A-12 | | | | | |

As is clear from the comparative examples A-1-A-12 shown in Tables 18-19, even if the second n-type nitride semiconductor layer 10 is provided, the value of the efficiency decrease degree at the low current density ΔEQE@0.3 A/cm² of the c-plane nitride semiconductor light-emitting diode is maintained at a large value. In other words, the value of the efficiency decrease degree at the low current density ΔEQE@0.3 A/cm² of the c-plane nitride semiconductor light-emitting diode is not improved.

### Comparative Example B

In the comparative example B, a simulation similar to that of the example 2 was conducted, except that a multi-quantum well layer composed of four In_{0.16}Ga_{0.84}N layers and three GaN layers was used instead of the active layer 9 composed of the single quantum well layer. Each of the In_{0.16}Ga_{0.84}N layers had a thickness of 3 nanometers. Similarly, each of the GaN layers had a thickness of 3 nanometers. Each of the GaN layers was interposed between the two In_{0.16}Ga_{0.84}N layers. The second n-type nitride semiconductor layer 10 formed of GaN was provided on the upper surface of the active layer 9. The first n-type nitride semiconductor layer 2 formed of GaN was provided on the lower surface of the active layer 9. Therefore, each of the In_{0.16}Ga_{0.84}N layers included in the multi-quantum well layer was interposed between the two GaN layers. In other words, the multi-quantum well layer was formed of a stacked structure of the In_{0.16}Ga_{0.84}N layer/the GaN layer/the In_{0.16}Ga_{0.84}N layer/the GaN layer/the In_{0.16}Ga_{0.84}N layer/the GaN layer/the In_{0.16}Ga_{0.84}N layer. Table 20 and Table 21 show the results of the simulation according to the comparative example B.

TABLE 20

| | | Impurity | Second n-type nitride | | | | |
|---|---|---|---|---|---|---|---|
| | | concentration | semiconductor layer 10 | | | n-type InGaN | |
| | | of p-type | | Impurity | | active layer 9 | |
| | Plane | GaN | Polar- | concentration | Thickness | Polar- | Thickness |
| | direction | layer 6 | ity | [cm⁻³] | [nm] | ity | [nm] |
| Comparative | 15 | 1.0E+18 | p | 1.0E+18 | 25 | n | 21 |
| example B-1 | degrees | | | | | | |
| Comparative | | | | 2.0E+17 | | | |
| example B-2 | | | | | | | |
| Comparative | | | n | 2.0E+17 | | | |
| example B-3 | | | | | | | |
| Comparative | | | | 1.0E+18 | | | |
| example B-4 | | | | | | | |

TABLE 21

| | | | | Efficiency decrease | Efficiency decrease |
|---|---|---|---|---|---|
| | | Low current | Large current | degree at the low | degree at the large |
| | | density | density | current density | current density |
| | EQE | EQE@0.3 | EQE@300 | ΔEQE@0.3 | ΔEQE@300 |
| | max | A/cm² | A/cm² | A/cm² | A/cm² |
| Comparative | 33.2 | 28.9 | 24.2 | 0.13 | 0.27 |
| example B-1 | | | | | |
| Comparative | 33.2 | 28.9 | 24.2 | 0.13 | 0.27 |
| example B-2 | | | | | |
| Comparative | 33.2 | 28.9 | 24.2 | 0.13 | 0.27 |
| example B-3 | | | | | |
| Comparative | 33.2 | 28.9 | 24.1 | 0.13 | 0.27 |
| example B-4 | | | | | |

In the comparative example B-1 and B-2, since the second n-type nitride semiconductor layer 10 is p-type, the nitride semiconductor light-emitting diodes according to the comparative examples B-1 and B-2 are typical nitride semiconductor light-emitting diodes each having a stacked structure of an n-type nitride semiconductor/an active layer/a p-type nitride semiconductor. The nitride semiconductor light-emitting diodes according to the comparative examples B-3 and B-4 had the same values of the efficiency decrease degree at the low current density as those of the nitride semiconductor light-emitting diodes according to the comparative examples B-1 and B-2 which are typical nitride semiconductor light-emitting diodes. For this reason, in light of the efficiency decrease degree at the low current density, it is meaningless to provide a nitride semiconductor light-emitting diode having a multi-quantum well layer with the second n-type nitride semiconductor layer 10.

### INDUSTRIAL APPLICABILITY

The nitride semiconductor light-emitting diode according to the present invention can be used for an illumination device, a liquid crystal backlight, or a headlamp for vehicles.

### REFERENTIAL SIGNS LIST

1 substrate
2 first n-type nitride semiconductor layer
5 second p-type nitride semiconductor layer
6 first p-type nitride semiconductor layer
7 n-side electrode
8 p-side electrode
9 active layer
10 second n-type nitride semiconductor layer

1. A nitride semiconductor light-emitting diode comprising:
an n-side electrode;
a p-side electrode;
a first n-type nitride semiconductor layer;
a p-type nitride semiconductor layer;
a second n-type nitride semiconductor layer; and
an active layer interposed between the first n-type nitride semiconductor layer and the p-type nitride semiconductor layer, wherein
the n-side electrode is electrically connected to the first n-type nitride semiconductor layer;
the p-side electrode is electrically connected to the p-type nitride semiconductor layer;
the active layer is composed of a single quantum well layer;
the single quantum well layer is formed of n-type InGaN;
the active layer has a principal surface of an m-plane having an off angle of not less than 0 degrees and not more than 15 degrees;
the active layer has a thickness of not less than 6 nanometers;
the second n-type nitride semiconductor layer is interposed between the active layer and the p-type nitride semiconductor layer;
either of the following requirement (A) and (B) is satisfied:
(A) the second n-type nitride semiconductor layer has a donor impurity concentration of not less than 3.0×10¹⁷ cm⁻³ and less than 1.5×10¹⁸ cm⁻³, and the p-type nitride semiconductor layer has an acceptor impurity concentration of not less than 5.0×10¹⁷ cm⁻³ and less than 1.0×10¹⁸ cm⁻³, or
(B) the second n-type nitride semiconductor layer has a donor impurity concentration of not less than 3.0×10¹⁷ cm⁻³ and not more than 2.5×10¹⁸ cm⁻³, and the p-type nitride semiconductor layer has an acceptor impurity concentration of not less than 1.0×10¹⁸ cm⁻³;
the second n-type nitride semiconductor layer has a thickness of not less than 25 nanometers; and
the following mathematical formula (I) is satisfied:
(Efficiency Decrease Degree at low current density ΔEQE@0.3 A/cm²)≦0.6 (I),
where
(Efficiency Decrease Degree at low current density ΔEQE@0.3 A/cm²)=(EQEmax−EQE@0.3 A/cm²)/EQEmax;
EQEmax represents the maximum of an external quantum efficiency of the nitride semiconductor light-emitting diode; and
EQE@0.3 A/cm² represents an external quantum efficiency of the nitride semiconductor light-emitting diode when a current of 0.3 A/cm² flows through the nitride semiconductor light-emitting diode.

2. The nitride semiconductor light-emitting diode according to claim 1, wherein
the active layer has a thickness of not more than 40 nanometers.

3. The nitride semiconductor light-emitting diode according to claim 1, wherein
the following mathematical formula (II) is satisfied.
(Efficiency Decrease Degree at low current density ΔEQE@0.3 A/cm²)≦0.5 (II)

4. The nitride semiconductor light-emitting diode according to claim 2, wherein
the active layer has a thickness of not more than 15 nanometers.

5. The nitride semiconductor light-emitting diode according to claim 1, wherein
the requirement (B) is satisfied; and
the p-type nitride semiconductor layer has an acceptor impurity concentration of not more than 2.0×10¹⁸ cm⁻³.

6. The nitride semiconductor light-emitting diode according to claim 1, wherein
the second n-type nitride semiconductor layer contains at least one donor selected from the group consisting of silicon, oxygen, and carbon.

7. A nitride semiconductor light-emitting diode comprising:
an n-side electrode;
a p-side electrode;
a first n-type nitride semiconductor layer;
a p-type nitride semiconductor layer;
a second n-type nitride semiconductor layer; and
an active layer interposed between the first n-type nitride semiconductor layer and the p-type nitride semiconductor layer, wherein
the n-side electrode is electrically connected to the first n-type nitride semiconductor layer;
the p-side electrode is electrically connected to the p-type nitride semiconductor layer;
the active layer is composed of a single quantum well layer;
the single quantum well layer is formed of n-type InGaN;
the active layer has a principal surface of an m-plane having an off angle of not less than 0 degrees and not more than 15 degrees;
the active layer has a thickness of not less than 6 nanometers;
the second n-type nitride semiconductor layer is interposed between the active layer and the p-type nitride semiconductor layer;
either of the following requirement (A) and (B) is satisfied;
(A) the second n-type nitride semiconductor layer has a donor impurity concentration of not less than 3.0×10¹⁷ cm⁻³ and less than 1.5×10¹⁸ cm⁻³, and the p-type nitride semiconductor layer has an acceptor impurity concentration of not less than 5.0×10¹⁷ cm⁻³ and less than 1.0×10¹⁸ cm⁻³, or
(B) the second n-type nitride semiconductor layer has a donor impurity concentration of not less than 3.0×10¹⁷ cm⁻³ and not more than 2.5×10¹⁸ cm⁻³, and the p-type nitride semiconductor layer has an acceptor impurity concentration of not less than 1.0×10¹⁸ cm⁻³;
the second n-type nitride semiconductor layer has a thickness of not less than 25 nanometers.

8. A nitride semiconductor light-emitting diode comprising:
an n-side electrode;
a p-side electrode;
a first n-type nitride semiconductor layer;
a p-type nitride semiconductor layer;
a second n-type nitride semiconductor layer; and
an active layer interposed between the first n-type nitride semiconductor layer and the p-type nitride semiconductor layer, wherein
the n-side electrode is electrically connected to the first n-type nitride semiconductor layer;
the p-side electrode is electrically connected to the p-type nitride semiconductor layer;
the active layer is composed of a single quantum well layer;
the single quantum well layer is formed of n-type InGaN;
the following mathematical formula (I) is satisfied:
(Efficiency Decrease Degree at low current density ΔEQE@0.3 A/cm²)≦0.6 (I),
where
(Efficiency Decrease Degree at low current density ΔEQE@0.3 A/cm²)=(EQEmax−EQE@0.3 A/cm²)/EQEmax;
EQEmax represents the maximum of an external quantum efficiency of the nitride semiconductor light-emitting diode; and
EQE@0.3 A/cm² represents an external quantum efficiency of the nitride semiconductor light-emitting diode when a current of 0.3 A/cm² flows through the nitride semiconductor light-emitting diode.
